(19) United States
(12) Patent Application Publication
(10) Pub. No.: US 2024/0178246 A1
(43) Pub. Date: May 30, 2024

(54) PHOTOELECTRIC CONVERSION APPARATUS, EQUIPMENT

(71) Applicant: CANON KABUSHIKI KAISHA, Tokyo (JP)

(72) Inventor: HIDEO KOBAYASHI, Tokyo (JP)

(21) Appl. No.: 18/513,978

(22) Filed: Nov. 20, 2023

(30) Foreign Application Priority Data
Nov. 30, 2022 (JP) 2022-190918

(51) Int. Cl. H01L 27/146

(52) U.S. Cl. CPC H01L 27/14614; H01L 27/14643

(57) ABSTRACT

A photoelectric conversion apparatus includes a pixel, a signal line, first and second transistors, and first and second switches. The pixel generates a pixel signal through photoelectric conversion that is output the signal line. The first and second transistors are connected to the signal line. The first switch is connected to the first transistor, and the second switch is connected to the second transistor. The first transistor and the second transistor are connected to the signal line in parallel with each other. A gate of the first transistor is connected to a first bias line, a gate of the second transistor is connected to a second bias line, and the first bias line and the second bias line are electrically separated from each other. A first control line of the first switch and a second control line of the second switch are electrically separated from each other.

### BACKGROUND

### Field

The present disclosure relates to a photoelectric conversion apparatus and equipment.

### Description of the Related Art

There are known photoelectric conversion apparatuses including pixels configured to generate pixel signals through photoelectric conversion and signal lines configured to output the pixel signals. Japanese Patent Application Laid-Open No. 2021-019256 discusses a photoelectric conversion apparatus with a configuration that includes signal lines and a circuit that suppresses a picked-up image from decreasing in quality by limiting a voltage variable range of the signal lines.

Among the known photoelectric conversion apparatuses, there include photoelectric conversion apparatuses having transistors connected to the signal lines configured to output the pixel signals where there is switching between the plurality of transistors.

### SUMMARY

The present disclosure is directed to providing a photoelectric conversion apparatus with improved performance.

According to an aspect of the present disclosure, a photoelectric conversion apparatus includes a pixel configured to generate a pixel signal through photoelectric conversion, a signal line to which the pixel signal is output, a first transistor connected to the signal line, a second transistor connected to the signal line, a first switch connected to the first transistor, and a second switch connected to the second transistor, wherein the first transistor and the second transistor are connected to the signal line in parallel with each other, wherein a gate of the first transistor is connected to a first bias line, wherein a gate of the second transistor is connected to a second bias line, wherein the first bias line and the second bias line are electrically separated from each other, and wherein a first control line of the first switch and a second control line of the second switch are electrically separated from each other.

Further features of the present disclosure will become apparent from the following description of exemplary embodiments with reference to the attached drawings.

### BRIEF DESCRIPTION OF THE DRAWINGS

FIG. 1 is a circuit diagram illustrating a photoelectric conversion apparatus according to a first exemplary embodiment.

FIG. 2 is a circuit diagram illustrating the photoelectric conversion apparatus according to the first exemplary embodiment.

FIG. 3 is a drive timing chart illustrating the photoelectric conversion apparatus according to the first exemplary embodiment.

FIG. 4 is a circuit diagram illustrating a reference photoelectric conversion apparatus.

FIG. 5 is a circuit diagram illustrating a photoelectric conversion apparatus according to a second exemplary embodiment.

FIG. 6 is a drive timing chart illustrating the photoelectric conversion apparatus according to the second exemplary embodiment.

FIG. 7 is a circuit diagram illustrating a photoelectric conversion apparatus according to a third exemplary embodiment.

FIG. 8 is a drive timing chart illustrating a photoelectric conversion apparatus according to a fourth exemplary embodiment.

FIG. 9 is a drive timing chart illustrating the photoelectric conversion apparatus according to the fourth exemplary embodiment.

FIG. 10 is a drive timing chart illustrating the photoelectric conversion apparatus according to the fourth exemplary embodiment.

FIG. 11 is a circuit diagram illustrating a photoelectric conversion apparatus according to a fifth exemplary embodiment.

FIG. 12 is a circuit diagram illustrating a photoelectric conversion apparatus according to a sixth exemplary embodiment.

FIGS. 13A, 13B, and 13C are schematic diagrams illustrating equipment according to a seventh exemplary embodiment.

### DESCRIPTION OF THE EMBODIMENTS

Various exemplary embodiments will be described below with reference to the drawings. The below-described exemplary embodiments are not intended to limit the scope of the disclosure. While a plurality of features according to the exemplary embodiments is described below, not all of the plurality of features are used in the disclosure, and the plurality of features can be combined as appropriate. Further, in the attached drawings, like numbers refer to the same or similar components, and redundant descriptions thereof are omitted. Further, sensors for image capturing will be mainly described as an example of a photoelectric conversion apparatus according to the exemplary embodiments. However, the exemplary embodiments are not limited to the sensors for image capturing and are also applicable to other examples of photoelectric conversion apparatuses. Examples thereof include image capturing apparatuses, distance measurement apparatuses (apparatuses for measuring distances using focus detection or Time-of-Flight (ToF)), and light metering apparatuses (apparatuses for measuring quantities of incident light).

In the present specification, the phrase “members A and B are electrically connected to each other” is not limited to a case where the members A and B are connected directly to each other. For example, the members A and B can be connected electrically to each other with another member C connected between the members A and B.

Metal members, such as lines and pads, that are described in the present specification can be composed of a single element metal or a mixture (alloy). For example, a line described as a copper line can be composed of copper alone or can be a copper line that mainly contains copper and further contains another component. Further, for example, a pad connected to an external terminal can be composed of aluminum alone or can be a pad that mainly contains aluminum and further contains another component. The copper lines and the aluminum pads described herein are merely examples and can be changed to various metals. Further, the lines and pads that are described herein are merely examples of metal members used in photoelectric conversion apparatuses, and application to other metal members are also possible.

Hereinafter, the charge that photoelectric conversion portions in pixels accumulate is electrons. Further, all the transistors of the pixels are N-channel type metal oxide semiconductor (N-channel type MOS) transistors (hereinafter, abbreviated as “NMOS transistor”). However, the charge that the photoelectric conversion portions accumulate can be holes. In this case, the transistors of the pixels can be P-channel type metal oxide semiconductor (P-channel type MOS) transistors (hereinafter, abbreviated as “PMOS transistor”). Specifically, the conductivity of the transistors can be changed based on the polarity of the charge used as signals.

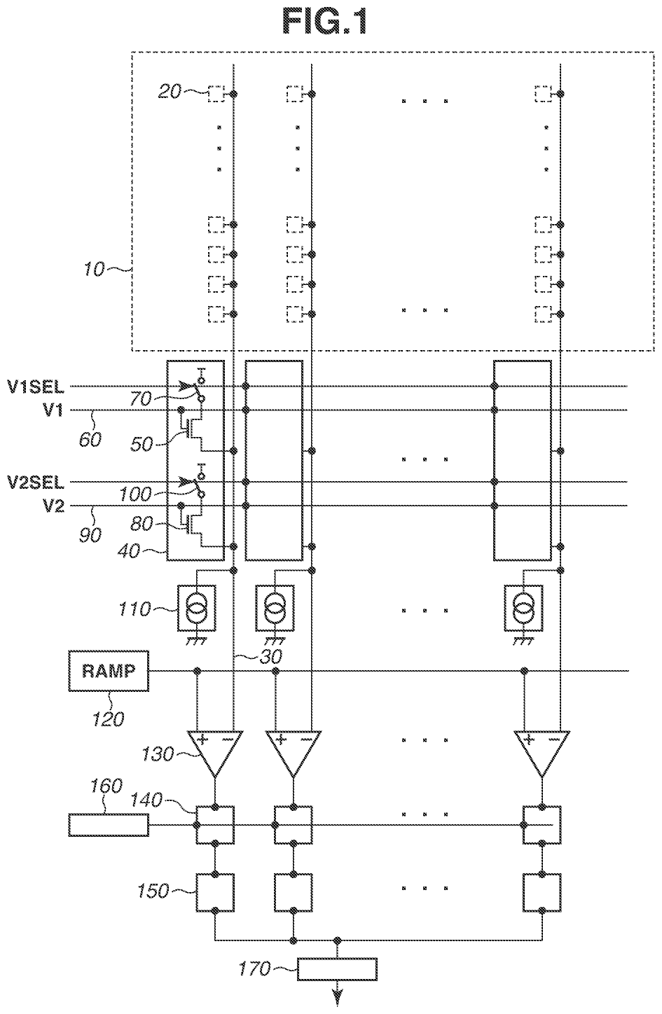

A photoelectric conversion apparatus according to a first exemplary embodiment of the present disclosure will be described below with reference to FIGS. 1 to 3.

FIG. 1 illustrates an example of a circuit diagram illustrating the photoelectric conversion apparatus according to the present exemplary embodiment.

As illustrated in FIG. 1, the photoelectric conversion apparatus includes a pixel array portion 10. The pixel array portion 10 includes pixels 20 arranged in a matrix form with a plurality of rows and a plurality of columns. The pixels 20 generate pixel signals through photoelectric conversion. The pixel array portion 10 includes signal lines 30 each arranged to the corresponding column of the columns of the pixels 20. The pixels 20 each output the pixel signals to the corresponding signal line of the signal lines 30.

The photoelectric conversion apparatus includes signal line drive portions 40. In each signal line drive portion 40, a first transistor 50, a first bias line 60, a first switch 70, a second transistor 80, a second bias line 90, and a second switch 100 are arranged. The first transistor 50 and the second transistor 80 can differ from each other in at least one of threshold voltage, gate width, and gate length. Further, the first transistor 50 and the second transistor 80 can be the same in threshold voltage, gate width, and gate length. The first transistor 50 and the second transistor 80 can be each an N-type transistor or a P-type transistor.

The first transistor 50 is connected to the corresponding signal line 30 via the source of the first transistor 50, and the second transistor 80 is connected to the corresponding signal line 30 via the source of the second transistor 80. Further, the first transistor 50 and the second transistor 80 are connected to the corresponding signal line 30 in parallel with each other. Further, the first switch 70 is connected between the drain of the first transistor 50 and a power supply voltage node and is driven by a control signal V1SEL. Further, the second switch 100 is connected between the drain of the second transistor 80 and a power supply voltage node and is driven by a control signal V2SEL. Further, the first bias line 60 is connected to the gate of the first transistor 50. Further, the second bias line 90 is connected to the gate of the second transistor 80. Further, a voltage V1 is supplied to the gate of the first transistor 50 via the first bias line 60. Further, a voltage V2 is supplied to the gate of the second transistor 80 via the second bias line 90. The voltages V1 and V2 differ from each other, and the first bias line 60 and the second bias line 90 are electrically separated from each other.

The photoelectric conversion apparatus includes current sources 110, a ramp signal generation circuit 120, comparators 130, first memories 140, second memories 150, a counter 160, and a processing circuit 170. The current sources 110 supply voltages and currents to the signal lines 30. The ramp signal generation circuit 120 generates ramp signals RAMP and feeds the ramp signals RAMP to the comparators 130. The ramp signals RAMP are signals that change in voltage over time. The comparators 130 output comparison result signals to the first memories 140. The comparison result signals indicate results of comparing the pixel signals output from the signal lines 30 and the ramp signals RAMP.

The counter 160 generates count signals representing the passage of time and outputs the count signals to the first memories 140. The first memories 140 hold the count signals output from the counter 160 based on changes in signal level of the comparison result signals output from the comparators 130. Consequently, the count signals of signal values corresponding to values of the pixel signals are held as digital signals corresponding to the pixel signals in the first memories 140, and the pixel signals output from the pixels 20 are analog-to-digital (AD) converted. The digital signals held in the first memories 140 are transferred to the second memories 150. The processing circuit 170 scans the second memories 150 column by column and reads the digital signals from the second memories 150 arranged correspondingly to the columns of the pixels 20. Further, the processing circuit 170 performs various types of digital signal processing, such as amplification, noise reduction, addition, and correction on the read digital signals. Furthermore, the processing circuit 170 outputs the digital signals to the outside of the photoelectric conversion apparatus.

While the common counter 160 is used for the plurality of first memories 140 in the example illustrated in FIG. 1, a common count clock can be fed, and the counter 160 can be provided for each of the plurality of first memories 140.

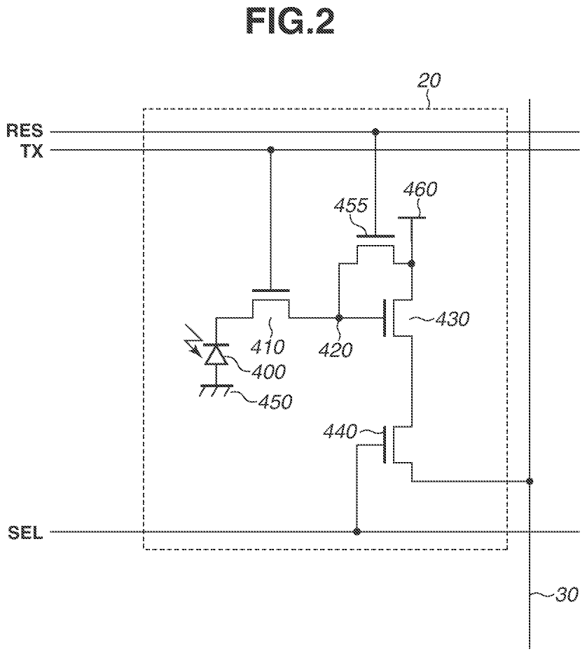

FIG. 2 illustrates an example of a circuit diagram illustrating each pixel 20 according to the present exemplary embodiment.

As illustrated in FIG. 2, the pixel 20 includes a photoelectric conversion portion 400, a transfer transistor 410, and a floating diffusion portion 420. Hereinafter in the present specification, the floating diffusion portion 420 is sometimes referred to as “FD portion 420” (FD is the abbreviation for floating diffusion). The pixel 20 further includes a reset transistor 455, an amplification transistor 430, and a selection transistor 440. The reset transistor 455 resets the FD portion 420. The amplification transistor 430 amplifies signals. Further, the photoelectric conversion portion 400 is electrically connected to a ground voltage node 450. Further, the reset transistor 455 and the amplification transistor 430 are electrically connected to a power supply voltage node 460, and the power supply voltage node 460 supplies a power supply voltage to the reset transistor 455 and the amplification transistor 430. The selection transistor 440 is sometimes omitted. The transfer transistor 410, the reset transistor 455, the amplification transistor 430, and the selection transistor 440 each can be an N-type transistor or a P-type transistor.

The photoelectric conversion portion 400 is, for example, a photodiode. The photoelectric conversion portion 400 receives light incident on the pixel 20 and generates a signal charge corresponding to the incident light. The reset transistor 455 is driven by a control signal RES. When the reset transistor 455 is turned on, the FD portion 420 is reset to a voltage based on the power supply voltage. Then, when the reset transistor 455 is turned off, the resetting of the FD portion 420 is cancelled. The transfer transistor 410 is driven by a control signal TX. When the transfer transistor 410 is turned on, the signal charge generated by the photoelectric conversion portion 400 is transferred to the FD portion 420. The FD portion 420 functions as a charge-voltage conversion portion that temporarily holds the signal charge input from the photoelectric conversion portion 400 and converts the held signal charge into a voltage signal. The amplification transistor 430 amplifies a pixel signal converted by the FD portion 420. The selection transistor 440 is driven by a control signal SEL, connects the amplification transistor 430 to the signal line 30, and outputs the pixel signal amplified by the amplification transistor 430 to the signal line 30. Consequently, the signal line 30 outputs the pixel signal corresponding to the voltage of the FD portion 420.

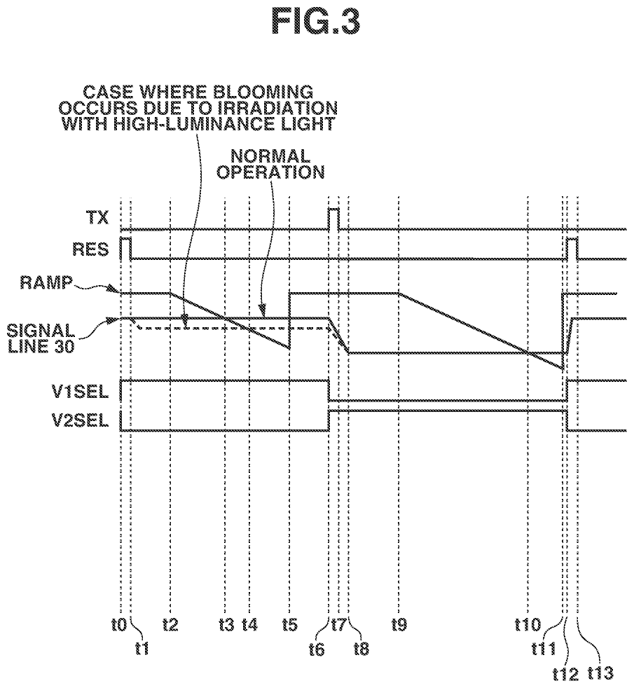

FIG. 3 illustrates an example of a timing chart illustrating a drive of the photoelectric conversion apparatus according to the present exemplary embodiment.

In FIG. 3, a horizontal axis represents time, and a vertical axis represents voltage. Further, control signals illustrated in FIG. 3 correspond to the control signals illustrated in FIGS. 1 and 2. During the period from time t2 to time t5, a reset-level signal of the pixel 20 is AD converted. Then, during the period from time t9 to time t11, a photoelectric conversion signal of the pixel 20 is AD converted. A dashed line represents a case where during the period from time t1 to time t8, high-luminance light strikes the photoelectric conversion portion 400, which causes blooming described below. Further, a solid line represents a case where during the period from time t1 to time t8, no high-luminance light strikes the photoelectric conversion portion 400, which causes no blooming (normal operation).

The reset-level signal and the photoelectric conversion signal that the pixel 20 outputs will now be described. When the reset transistor 455 is turned on, the FD portion 420 is reset to the voltage based on the power supply voltage. Then, when the reset transistor 455 is turned off, the resetting of the FD portion 420 is cancelled. The reset-level signal that the pixel 20 outputs is a signal that the amplification transistor 430 outputs correspondingly to the voltage of the FD portion 420 after the cancellation of the resetting. The reset-level signal is a signal containing noise components of the pixel 20.

Thereafter, when the transfer transistor 410 is turned on, a signal charge generated by the photoelectric conversion portion 400 photoelectrically converting incident light is transferred to the FD portion 420. The amplification transistor 430 outputs, as a photoelectric conversion signal, a signal corresponding to the voltage of the FD portion 420 after the transfer of the signal charge. The pixel signals that the pixel 20 outputs are the reset-level signal and the photoelectric conversion signal.

At time t0, the control signal RES is changed to a high level. As a result, the reset transistor 455 is turned on, and the FD portion 420 is reset. Accordingly, the voltage of the signal line 30 is changed to a reset level. Further, at time t0, the control signal V1SEL is changed to a high level. As a result, the first switch 70 is changed to an on state, which causes the first transistor 50 connected to the signal line 30 to function. Further, at time t0, the control signal V2SEL is changed to a low level. As a result, the second switch 100 is changed to an off state, which causes the second transistor 80 connected to the signal line 30 not to function. A mode in which the first switch 70 is changed to the on state and the second switch 100 is changed to the off state will be referred to as “first mode”. At time t1, the control signal RES is changed to a low level, and the reset transistor 455 is turned off. At this time, if high-luminance light strikes the photoelectric conversion portion 400, signal charge generated by the photoelectric conversion portion 400 leaks to the FD portion 420 although the transfer transistor 410 is turned off. This causes a decrease in voltage of the FD portion 420 and a decrease in voltage of the signal line 30. An operation state at this time is referred to as blooming, which is represented by the dashed line in FIG. 3. If blooming occurs, the voltage of the signal line 30 decreases, compared to the normal operation with no blooming due to no high-luminance light. The amount of decrease in voltage of the signal line 30 (a level at which the dashed line stops descending) with blooming is determined based on the threshold voltage, the gate width, and the gate length of the first transistor 50 and the voltage V1 supplied to the gate of the first transistor 50 via the first bias line 60. This is because a decrease in voltage of the FD portion 420 causes the first transistor 50 to become greater in driving power than the amplification transistor 430, and the voltage of the signal line 30 is limited to a first range. Specifically, the first transistor 50 limits the variable range of the voltage of the signal line 30 to the first range.

During the period from time t2 to time t5, the ramp signal RAMP fed to the comparator 130 changes in voltage over time. If no blooming occurs, at time t3, the magnitude relationship between the ramp signal RAMP and the pixel signal of the signal line 30 that are inputs of the comparator 130 is changed, which causes a change in an output of the comparator 130. On the other hand, if blooming occurs, at time t4, the magnitude relationship between the ramp signal RAMP and the pixel signal of the signal line 30 that are inputs of the comparator 130 is changed, which causes a change in an output of the comparator 130. The time it takes for the change to occur is measured by the counter 160, and the measured time is held in the first memory 140, whereby AD conversion is performed on the reset-level signal. At time t5, the ramp signal RAMP is reset. At this time, if blooming occurs, an error occurs in the result of the AD conversion on the reset-level signal. This will be described below.

At time t6, the control signal TX is changed to a high level. As a result, the transfer transistor 410 is turned on, and the signal charge is transferred from the photoelectric conversion portion 400 to the FD portion 420. The voltage of the FD portion 420 decreases according to the amount of the transferred signal charge. Further, at time t6, the control signal V1SEL is changed to a low level. As a result, the first switch 70 is changed to the off state, which causes the first transistor 50 connected to the signal line 30 not to function. Further, at time t6, the control signal V2SEL is changed to a high level. As a result, the second switch 100 is changed to the on state, which causes the second transistor 80 connected to the signal line 30 to function. A mode in which the first switch 70 is changed to the off state and the second switch 100 is changed to the on state will be referred to as “second mode”. According to the present exemplary embodiment, the first mode is switched to the second mode at time t6.

During the normal operation with no blooming, a decrease in voltage of the FD portion 420 causes a decrease in voltage of the signal line 30. On the other hand, if blooming occurs, since the amplification transistor 430 is off, the voltage of the signal line 30 is not affected by a decrease in voltage of the FD portion 420. However, switching from the first transistor 50 to the second transistor 80 causes a decrease in voltage of the signal line 30. Specifically, the second transistor 80 limits the variable range of the voltage of the signal line 30 to a second range different from the first range. The voltage V2 supplied to the gate of the second transistor 80 is lower than the voltage V1 supplied to the gate of the first transistor 50.

At time t7, the control signal TX is changed to a low level, which causes the transfer transistor 410 to be turned off.

During the period from time t9 to time t11, the ramp signal RAMP fed to the comparator 130 changes in voltage again over time. Then, at time t10, the magnitude relationship between the ramp signal RAMP and the pixel signal of the signal line 30 that are inputs of the comparator 130 is changed, which causes a change in an output of the comparator 130 again. The time it takes for the change to occur is measured by the counter 160, and the measured time is held in the first memory 140, whereby AD conversion is performed on the photoelectric conversion signal. Finally, an output from the pixel 20 is obtained through a correlated double sampling (CDS) operation of performing differential processing between the result of the AD conversion on the photoelectric conversion signal and the result of the AD conversion on the reset-level signal. Even though blooming occurs, a saturated output is still obtained by maintaining an amount of decrease in potential of the signal line 30 at time t6 at a predetermined level or higher. Specifically, even though an error occurs in the result of the AD conversion on the reset-level signal as described above, a saturated output after CDS is still obtained, which is an appropriate result.

At time t11, the ramp signal RAMP is reset again. At time t12, the control signal RES is changed to a high level. As a result, the reset transistor 455 is turned on, and the FD portion 420 is reset. This causes the voltage of the signal line 30 to return to the reset level.

As described above, the photoelectric conversion apparatus according to the present exemplary embodiment includes the first transistors 50, the first bias line 60, the first switches 70, the second transistors 80, the second bias line 90, and the second switches 100. According to the present exemplary embodiment, the voltage supplied to the gates of the first transistors 50 and the voltage supplied to the gates of the second transistors 80 differ from each other, which makes it possible to change the driving power of the signal line drive portions 40. For example, the driving power of the signal line drive portions 40 that is suitable for an operation mode is selectable by switching between the first transistors 50 and the second transistors 80 based on the operation mode (such as a still image mode and a moving image mode). Thus, according to the present exemplary embodiment, switching the transistors connected to the signal lines 30 among the plurality of transistors with their gates to which different voltages are supplied achieves a function of limiting a lower limit of the voltage of the signal lines 30 and a function of switching the lower limit of the voltage. The charge that the photoelectric conversion portions 400 accumulate can be holes. In this case, a function of limiting an upper limit of the voltage of the signal lines 30 and a function of switching the upper limit of the voltage are achieved.

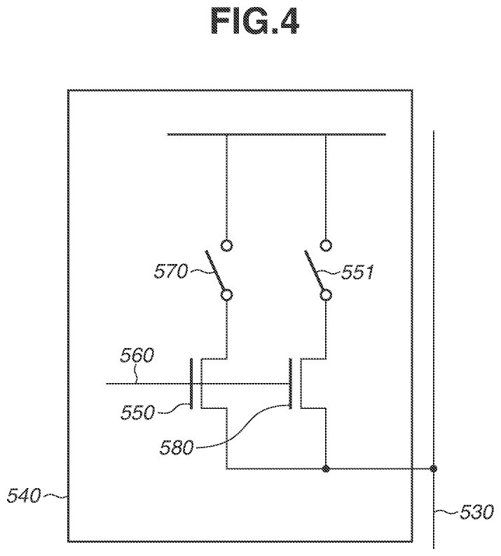

A reference example is illustrated in FIG. 4. In a photoelectric conversion apparatus in FIG. 4, a first transistor 550, a first bias line 560, a first switch 570, a second transistor 580, and a second switch 551 are arranged. A voltage is supplied to the gate of the first transistor 550 and the gate of the second transistor 580 via the first bias line 560. With the configuration illustrated in FIG. 4, switching the voltage applied to the single first bias line 560 so that the voltage decreases at a predetermined timing achieves functions similar to those according to the first exemplary embodiment. However, it takes time to switch the first transistor 550 and the second transistor 580 due to the necessity to discharge capacitances of the first transistor 550 and the second transistor 580 and effects of parasitic capacitance of the first bias line 60. On the other hand, according to the present exemplary embodiment illustrated in FIG. 1, the first bias line 60 connected to the gate of the first transistor 50 and the second bias line 90 connected to the gate of the second transistor 80 are separately provided. The above-described configuration according to the present exemplary embodiment allows high-speed switching of the lower limit of the voltage of the signal lines 30. The first transistor 550, the first bias line 560, the first switch 570, the second transistor 580, the second switch 551, and the signal line 530 in FIG. 4 respectively correspond to the first transistors 50, the first bias line 60, the first switches 70, the second transistors 80, the second switches 100, and the signal lines 30 in FIG. 1.

Further, in FIG. 4, the first transistor 550 and the second transistor 580 are connected to the first bias line 560 in the single signal line drive portion 540. On the other hand, according to the present exemplary embodiment illustrated in FIG. 1, only the first transistor 50 is connected to the first bias line 60 in each signal line drive portion 40. Specifically, the number of transistors connected to one bias line is smaller in the present exemplary embodiment than in the reference example, and the smaller the number of transistors, the smaller the transistor capacitance that affects the operations of the signal line drive portions 40 is. This makes it possible to perform an operation of switching the voltage V1 at high speed in switching the voltage V1 at a predetermined timing, such as a frame switch timing. Thus, the present exemplary embodiment allows improvement in performance of the photoelectric conversion apparatus.

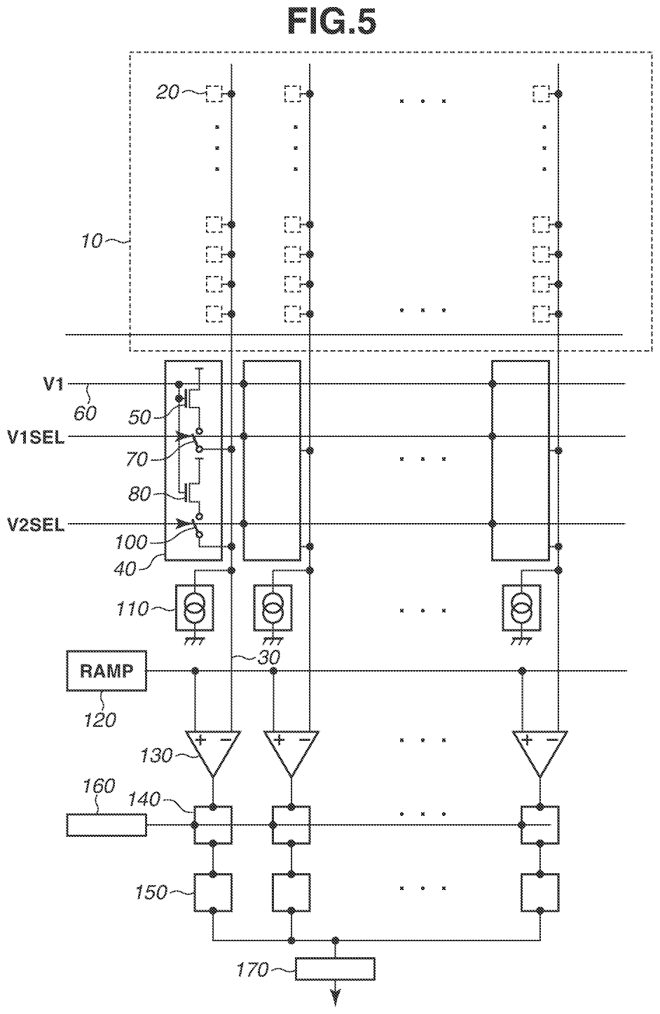

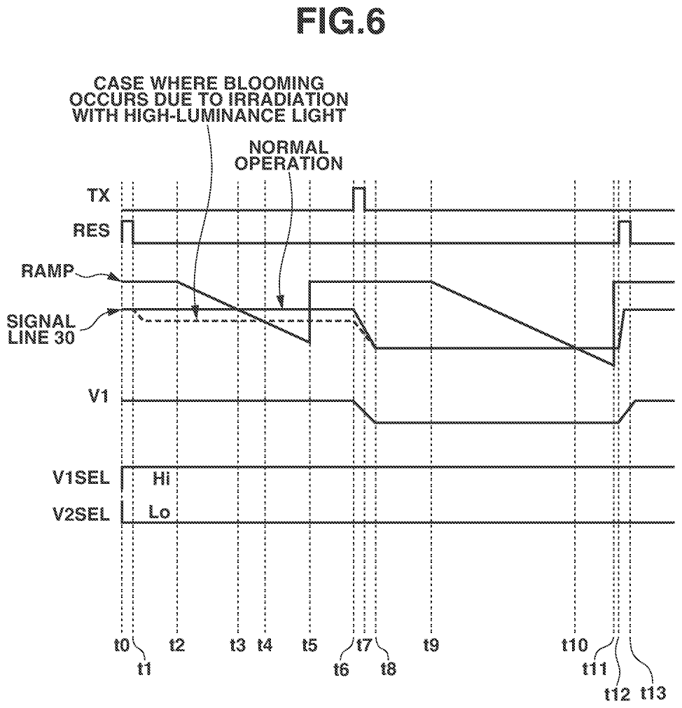

A photoelectric conversion apparatus according to a second exemplary embodiment of the present disclosure will be described below with reference to FIGS. 5 and 6. Like numbers refer to like components corresponding to the components according to the first exemplary embodiment, and redundant descriptions thereof are sometimes omitted or simplified.

The present exemplary embodiment differs from the first exemplary embodiment in that a common bias line is connected to the gate of the first transistor 50 and the gate of the second transistor 80. Further, the present exemplary embodiment differs from the first exemplary embodiment also in that the first switch 70 is connected between the first transistor 50 and the signal line 30 and the second switch 100 is connected between the second transistor 80 and the signal line 30. FIG. 5 illustrates an example of a circuit diagram illustrating the photoelectric conversion apparatus according to the present exemplary embodiment.

As illustrated in FIG. 5, the photoelectric conversion apparatus includes signal line drive portions 40. In each signal line drive portion 40, the first transistor 50, the first bias line 60, the first switch 70, the second transistor 80, and the second switch 100 are arranged. The first transistor 50 and the second transistor 80 differ from each other in at least one of threshold voltage, gate width, and gate length.

The first transistor 50 is connected to the signal line 30 via the source of the first transistor 50, and the second transistor 80 is connected to the signal line 30 via the source of the second transistor 80. Further, the first transistor 50 and the second transistor 80 are connected to the signal line 30 in parallel with each other. Further, the first switch 70 is connected between the source of the first transistor 50 and the signal line 30 and is driven by the control signal V1SEL. Further, the second switch 100 is connected between the source of the second transistor 80 and the signal line 30 and is driven by the control signal V2SEL. Further, the first bias line 60 is connected to the gate of the first transistor 50 and the gate of the second transistor 80. The voltage V1 is supplied to the gate of the first transistor 50 and the gate of the second transistor 80 via the first bias line 60.

FIG. 6 illustrates an example of a timing chart illustrating a drive of the photoelectric conversion apparatus according to the present exemplary embodiment.

In FIG. 6, a horizontal axis represents time, and a vertical axis represents voltage. Further, control signals illustrated in FIG. 6 correspond to the control signals illustrated in FIGS. 2 and 5. During the period from time t2 to time t5, the reset-level signal of the pixel 20 is AD converted. Then, during the period from time t9 to time t11, the photoelectric conversion signal of the pixel 20 is AD converted. A dashed line represents a case where high-luminance light strikes the photoelectric conversion portion 400 during the period from time t1 to time t8, which causes blooming described below. Further, a solid line represents a case where no high-luminance light strikes the photoelectric conversion portion 400 during the period from time t1 to time t8, which causes no blooming described below (normal operation).

At time t0, the control signal RES is changed to a high level. As a result, the reset transistor 455 is turned on, and the FD portion 420 is reset. Accordingly, the voltage of the signal line 30 is changed to a reset level. Further, at time t0, the control signal V1SEL is changed to a high level. As a result, the first switch 70 is changed to the on state, which causes the first transistor 50 connected to the signal line 30 to function. Further, at time t0, the control signal V2SEL is changed to a low level. As a result, the second switch 100 is changed to the off state, which causes the second transistor 80 connected to the signal line 30 not to function. The mode in which the first switch 70 is changed to the on state and the second switch 100 is changed to the off state will be referred to as “first mode”. At time t1, the control signal RES is changed to a low level, and the reset transistor 455 is turned off. At this time, if high-luminance light strikes the photoelectric conversion portion 400, although the transfer transistor 410 is turned off, signal charge generated by the photoelectric conversion portion 400 leaks to the FD portion 420. This causes a decrease in voltage of the FD portion 420 and a decrease in voltage of the signal line 30. The operation state at this time is referred to as “blooming”, which is represented by the dashed line in FIG. 6. If blooming occurs, the voltage of the signal line 30 decreases, compared to the normal operation in which no high-luminance light strikes the photoelectric conversion portion 400, which causes no blooming. The amount of decrease in voltage of the signal line 30 (a level at which the dashed line stops descending) with blooming is determined based on the threshold voltage, the gate width, and the gate length of the first transistor 50 and the voltage V1 supplied to the gate of the first transistor 50 via the first bias line 60. This is because the decrease in voltage of the FD portion 420 causes the first transistor 50 to become greater in driving power than the amplification transistor 430, and the voltage of the signal line 30 is limited to a first range. Specifically, the first transistor 50 limits the variable range of the voltage of the signal line 30 to the first range.

During the period from time t2 to time t5, the ramp signal RAMP fed to the comparator 130 changes in voltage over time. If no blooming occurs, at time t3, the magnitude relationship between the ramp signal RAMP and the pixel signal of the signal line 30 that are inputs of the comparator 130 is changed, and this changes an output of the comparator 130. On the other hand, if blooming occurs, at time t4, the magnitude relationship between the ramp signal RAMP and the pixel signal of the signal line 30 that are inputs of the comparator 130 is changed, and this changes an output of the comparator 130. The time it takes for the change to occur is measured by the counter 160, and the measured time is held in the first memory 140, whereby AD conversion is performed on the reset-level signal. At time t5, the ramp signal RAMP is reset. At this time, if blooming occurs, an error occurs in the result of the AD conversion on the reset-level signal. This will be described below.

At time t6, the control signal TX is changed to a high level. As a result, the transfer transistor 410 is turned on, and the signal charge is transferred from the photoelectric conversion portion 400 to the FD portion 420. The voltage of the FD portion 420 decreases according to the amount of the transferred signal charge. Further, during the period from time t6 to time t8, the voltage V1 changes in value over time.

During the normal operation with no blooming, a decrease in voltage of the FD portion 420 causes a decrease in voltage of the signal line 30. On the other hand, if blooming occurs, since the amplification transistor 430 is off, the voltage of the signal line 30 is not affected by a decrease in voltage of the FD portion 420. However, a decrease in the voltage V1 causes a decrease in voltage of the signal line 30. Specifically, the first transistor 50 limits the variable range of the voltage of the signal line 30 to a second range different from the first range.

At time t7, the control signal TX is changed to a low level, and the transfer transistor 410 is turned off.

During the period from time t9 to time t11, the ramp signal RAMP fed to the comparator 130 changes in voltage again over time. Then, at time t10, the magnitude relationship between the ramp signal RAMP and the pixel signal of the signal line 30 that are inputs of the comparator 130 is changed, and this changes an output of the comparator 130 again. The time it takes for the change to occur is measured by the counter 160, and the measured time is held in the first memory 140, whereby AD conversion is performed on the photoelectric conversion signal. Finally, an output from the pixel 20 is obtained by a CDS operation of performing differential processing between the result of the AD conversion on the photoelectric conversion signal and the result of the AD conversion on the reset-level signal. Even though blooming occurs, a saturated output is still obtained by maintaining an amount of decrease in potential of the signal line 30 at time t6 at a predetermined level or higher. Specifically, even though an error occurs in the result of the AD conversion on the reset-level signal as described above, a saturated output after CDS is still obtained, which is an appropriate result.

At time t11, the ramp signal RAMP is reset again. At time t12, the control signal RES is changed to a high level. As a result, the reset transistor 455 is turned on, and the FD portion 420 is reset. This causes the voltage of the signal line 30 to return to the reset level.

As described above, the photoelectric conversion apparatus according to the present exemplary embodiment includes the first transistors 50, the first bias line 60, the first switches 70, the second transistors 80, and the second switches 100. According to the present exemplary embodiment, the first transistors 50 and the second transistors 80 differ from each other in at least one of threshold voltage, gate width, and gate length. This makes it possible to change the driving power of the signal line drive portions 40. For example, the driving power of the signal line drive portions 40 that is suitable for an operation mode is selectable by switching the first transistors 50 and the second transistors 80 based on the operation mode (such as a still image mode and a moving image mode). Thus, according to the present exemplary embodiment, switching the plurality of transistors differing from each other in at least one of threshold voltage, gate width, and gate length achieves the function of limiting the lower limit of the voltage of the signal lines 30 and the function of switching the lower limit of the voltage. The charge that the photoelectric conversion portions 400 accumulate can be holes, and in this case, the function of limiting the upper limit of the voltage of the signal lines 30 and the function of switching the upper limit of the voltage are achieved.

Furthermore, the present exemplary embodiment prevents interference between the pixel columns compared to the first exemplary embodiment illustrated in FIG. 1. In FIG. 1, there is a gate-source capacitance of the first transistor 50 between each signal line 30 and the first bias line 60. Further, in FIG. 1, there is a gate-source capacitance of the second transistor 80 between each signal line 30 and the second bias line 90. Thus, if the voltage of a signal line 30 fluctuates, that fluctuation is transmitted to the first bias line 60 and the second bias line 90 via the gate-source capacitances. The fluctuation is eventually transmitted to other pixel columns, which causes interference between the pixel columns. On the other hand, according to the present exemplary embodiment illustrated in FIG. 5, only either the first switch 70 or the second switch 100 is changed to the on state, so that a fluctuation in voltage of the signal lines 30 is transmitted to the first bias line 60 via a gate-source capacitance of a single transistor. Thus, in the present exemplary embodiment, a simultaneous fluctuation in voltage of a plurality of bias lines does not occur compared to FIG. 1, which prevents interference between the pixel columns. A fluctuation in voltage of the control signal V1SEL, which drives the first switch 70, and the control signal V2SEL, which drives the second switch 100, may cause interference between the columns. However, the control signals V1SEL and V2SEL are not analog signals but logic signals, which prevents fluctuation in voltage using a repeat buffer easily.

Further, the present exemplary embodiment reduces the parasitic capacitance between the signal lines 30 and the first bias line 60 and prevents interference between the pixel columns compared to the reference example in FIG. 4. In FIG. 4, there are gate-source capacitances of the first transistor 550 and the second transistor 580 between the signal line 530 and the first bias line 560. Thus, if the voltage of the signal line 30 fluctuates, that fluctuation is transmitted to the first bias line 560 via the gate-source capacitances. Then, the fluctuation is eventually transmitted to other pixel columns, which causes interference between the pixel columns.

On the other hand, according to the present exemplary embodiment illustrated in FIG. 5, only either the first switch 70 or the second switch 100 is changed to the on state, so that a fluctuation in voltage of a signal line 30 is transmitted to the first bias line 60 via a gate-source capacitance of a single transistor. Thus, in the present exemplary embodiment, the parasitic capacitances between the signal lines 30 and the first bias line 60 are reduced, which prevents interference between the pixel columns, compared to FIG. 4. Thus, the present exemplary embodiment allows improvement in performance of the photoelectric conversion apparatus.

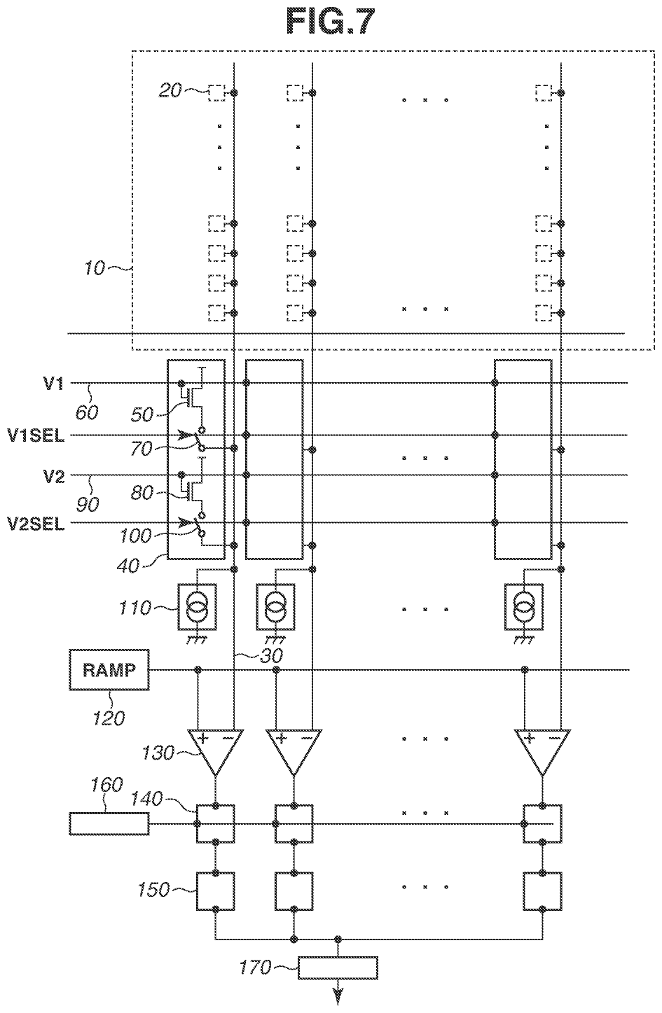

A photoelectric conversion apparatus according to a third exemplary embodiment of the present disclosure will be described below with reference to FIG. 7. Like numbers refer to like components corresponding to components according to the first and second exemplary embodiments, and redundant descriptions thereof will be sometimes omitted or simplified.

The present exemplary embodiment differs from the first exemplary embodiment in that the first switch 70 is connected between the first transistor 50 and the signal line 30 and the second switch 100 is connected between the second transistor 80 and the signal line 30. FIG. 7 illustrates an example of a circuit diagram illustrating the photoelectric conversion apparatus according to the present exemplary embodiment.

As illustrated in FIG. 7, the photoelectric conversion apparatus includes signal line drive portions 40. In each signal line drive portion 40, the first transistor 50, the first bias line 60, the first switch 70, the second transistor 80, the second bias line 90, and the second switch 100 are arranged. The first transistor 50 and the second transistor 80 can differ from each other in at least one of threshold voltage, gate width, and gate length. Further, the first transistor 50 and the second transistor 80 can be the same in threshold voltage, gate width, and gate length.

The first transistor 50 is connected to the signal line 30 via the source of the first transistor 50, and the second transistor 80 is connected to the signal line 30 via the source of the second transistor 80. Further, the first transistor 50 and the second transistor 80 are connected to the signal line 30 in parallel with each other. Further, the first switch 70 is connected between the source of the first transistor 50 and the signal line 30 and is driven by the control signal V1SEL. Further, the second switch 100 is connected between the source of the second transistor 80 and the signal line 30 and is driven by the control signal V2SEL. Further, the first bias line 60 is connected to the gate of the first transistor 50. Further, the second bias line 90 is connected to the gate of the second transistor 80. Further, the voltage V1 is supplied to the gate of the first transistor 50 via the first bias line 60. Further, the voltage V2 is supplied to the gate of the second transistor 80 via the second bias line 90. The voltages V1 and V2 differ from each other, and the first bias line 60 and the second bias line 90 are electrically separated from each other.

As described above, the photoelectric conversion apparatus according to the present exemplary embodiment includes the first transistors 50, the first bias line 60, the first switches 70, the second transistors 80, the second bias line 90, and the second switches 100. According to the present exemplary embodiment, different voltages are supplied to the gates of the first transistors 50 and the second transistors 80 to change the driving power of the signal line drive portions 40. For example, the driving power of the signal line drive portions 40 that is suitable for an operation mode is selectable by switching the first transistors 50 and the second transistors 80 based on the operation mode (such as a still image mode and a moving image mode). Thus, according to the present exemplary embodiment, switching the plurality of transistors with the gates to which different voltages are supplied achieves the function of limiting the lower limit of the voltage of the signal lines 30 and the function of switching the lower limit of the voltage. The charge that the photoelectric conversion portions 400 accumulate can be holes, and in this case, the function of limiting the upper limit of the voltage of the signal lines 30 and the function of switching the upper limit of the voltage are achieved.

The present exemplary embodiment prevents interference between the pixel columns compared to the first exemplary embodiment illustrated in FIG. 1. In FIG. 1, there is a gate-source capacitance of the first transistor 50 between each signal line 30 and the first bias line 60. Further, in FIG. 1, there is a gate-source capacitance of the second transistor 80 between each signal line 30 and the second bias line 90. Thus, if the voltage of a signal line 30 fluctuates, that fluctuation is transmitted to the first bias line 60 and the second bias line 90 via the gate-source capacitances. The fluctuation is eventually transmitted to other pixel columns, which causes interference between the pixel columns. On the other hand, according to the present exemplary embodiment illustrated in FIG. 7, only either the first switch 70 or the second switch 100 is changed to the on state, so that a fluctuation in voltage of the signal lines 30 is transmitted to a single bias line via a gate-source capacitance of a single transistor. Thus, in the present exemplary embodiment, a simultaneous fluctuation in voltage of a plurality of bias lines does not occur compared to FIG. 1, which prevents interference between the pixel columns. A fluctuation in voltage of the control signal V1SEL, which drives the first switch 70, and the control signal V2SEL, which drives the second switch 100, can cause interference between the columns. However, the control signals V1SEL and V2SEL are not analog signals but logic signals, which prevents fluctuation in voltage using a repeat buffer easily. Thus, the present exemplary embodiment allows improvement in performance of the photoelectric conversion apparatus.

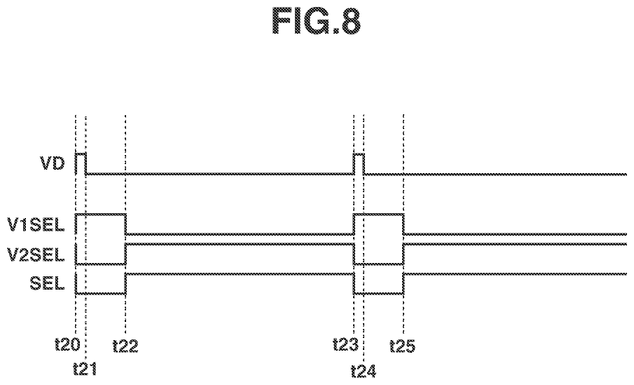

A photoelectric conversion apparatus according to a fourth exemplary embodiment of the present disclosure will be described below with reference to FIGS. 8 to 10. Like numbers refer to like components corresponding to components according to the first, second, and third exemplary embodiments, and redundant descriptions thereof will be sometimes omitted or simplified.

While the present exemplary embodiment is similar in configuration to the first exemplary embodiment illustrated in FIGS. 1 and 2 or the third exemplary embodiment in FIG. 7, the present exemplary embodiment differs in driving method. According to the first exemplary embodiment, as illustrated in FIG. 3, driving is performed to switch between the control signals V1SEL and V2SEL in one pixel signal reading. Further, the first transistor 50 and the second transistor 80 are used for the same purpose (to limit the lower limit of the voltage of the signal line 30) in one pixel signal reading. According to the present exemplary embodiment, on the other hand, driving is performed not to switch the control signals V1SEL and V2SEL in one pixel signal reading. Further, in one pixel signal reading, only either the first transistor 50 or the second transistor 80 is used, and the first transistor 50 and the second transistor 80 are used for different purposes from each other.

FIGS. 8 to 10 illustrate an example of a timing chart illustrating a drive of the photoelectric conversion apparatus according to the present exemplary embodiment. In FIGS. 8 to 10, a horizontal axis represents time, and a vertical axis represents voltage. Further, control signals in FIGS. 8 to 10 correspond to the control signals in FIGS. 1 and 2.

As illustrated in FIG. 8, during the period from time t20 to time t21, a control signal VD is changed to a high level. The control signal VD is a signal that is changed to a high level once in one frame. Further, during the period from time t20 to time t22, the control signal V1SEL is changed to a high level, and the control signal V2SEL is changed to a low level. The mode in which the first switch 70 is changed to the on state and the second switch 100 is changed to the off state will be referred to as “first mode”. Further, during the period from time t20 to time t22, the control signal SEL is changed to a low level. As a result, the selection transistor 440 is turned off, and no pixel signals are output from the pixel 20 to the signal line 30. As will be described in detail below, during the period from time t20 to time t22, a correction value acquisition operation is performed using the first transistor 50 instead of the pixels 20. Further, during the period from time t22 to time t23, the control signal V1SEL is changed to a low level, and the control signal V2SEL is changed to a high level. The mode in which the first switch 70 is changed to the off state and the second switch 100 is changed to the on state will be referred to as “second mode”. According to the present exemplary embodiment, the first mode and the second mode are switched at time t22. During the period from time t22 to time t23, the lower limit of the voltage of the signal line 30 is limited using the second transistor 80 as in the first exemplary embodiment.

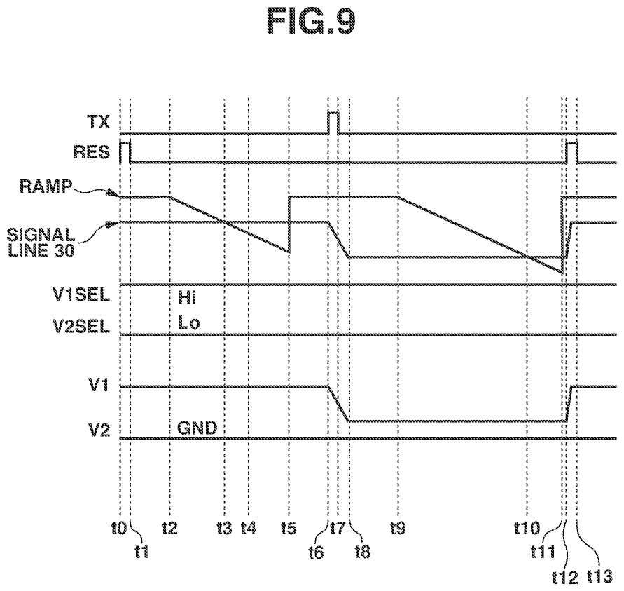

FIG. 9 illustrates one correction value acquisition operation during the period from time t20 to time t22 in FIG. 8. As described above, in FIG. 9, the control signal V1SEL is at a high level, the control signal V2SEL is at a low level, the first switch 70 is in the on state, and the second switch 100 is in the off state. Specifically, the first transistor 50 functions whereas the second transistor 80 does not function. In this state, the voltage V1 is supplied to the gate of the first transistor 50 and output to the signal line 30. By performing AD conversion on a signal corresponding to the voltage V1, for example, a circuit characteristic variation, which is a gain variation herein, of each column is acquired. The voltage V2 is set to the ground voltage.

During the period from time t2 to time t5, the ramp signal RAMP fed to the comparator 130 changes in voltage over time. At time t3, the magnitude relationship between the ramp signal RAMP and the pixel signal of the signal line 30 that are inputs of the comparator 130 is changed, and this changes an output of the comparator 130.

The time it takes for the change to occur is measured by the counter 160, and the measured time is held in the first memory 140, whereby AD conversion is performed on a reference-level signal. At time t5, the ramp signal RAMP is reset.

During the period from time t6 to time t8, the voltage V1 changes in value over time. Further, a decrease in the voltage V1 causes a decrease in voltage of the signal line 30.

During the period from time t9 to time t11, the ramp signal RAMP fed to the comparator 130 changes in voltage again over time. Then, at time t10, the magnitude relationship between the ramp signal RAMP and the signal of the signal line 30 that are inputs of the comparator 130 is changed, and this changes an output of the comparator 130 again. The time it takes for the change to occur is measured by the counter 160, and the measured time is held in the first memory 140, whereby AD conversion is performed on a signal-level signal. Then, a gain value is measured for each column by a CDS operation of performing differential processing between the result of the AD conversion on the signal-level signal and the result of the AD conversion on the reference-level signal, and a final gain error correction value is obtained. The above-described driving is performed a plurality of times during the period from time t20 to time t22 in FIG. 8, and the results are averaged to acquire a highly-accurate gain error correction value.

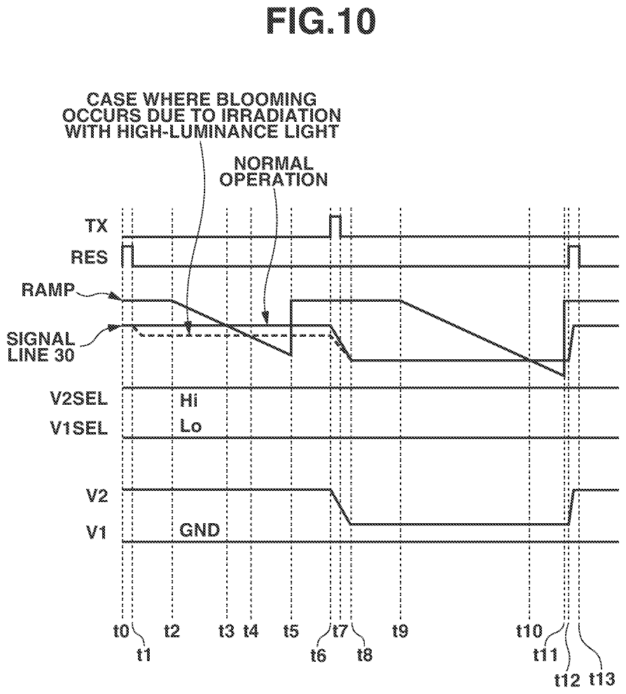

FIG. 10 illustrates one pixel signal reading operation during the period from time t22 to time t23 in FIG. 8. As described above, in FIG. 10, the control signal V1SEL is at a low level, the control signal V2SEL is at a high level, the first switch 70 is in the off state, and the second switch 100 is in the on state. Specifically, the first transistor 50 does not function whereas the second transistor 80 functions. During the period from time t2 to time t5, the reset-level signal of the pixel 20 is AD converted. Then, during the period from time t9 to time t11, the photoelectric conversion signal of the pixel 20 is AD converted. A dashed line represents a case where high-luminance light strikes the photoelectric conversion portion 400 during the period from time t1 to time t8, which causes blooming described below. Further, a solid line represents a case where no high-luminance light strikes the photoelectric conversion portion 400 during the period from time t1 to time t8, which causes no blooming described below (normal operation). The voltage V1 is set to the ground voltage.

At time t0, the control signal RES is changed to a high level. As a result, the reset transistor 455 is turned on, and the FD portion 420 is reset. Accordingly, the voltage of the signal line 30 is changed to a reset level. At time t1, the control signal RES is changed to a low level, and the reset transistor 455 is turned off. At this time, if high-luminance light strikes the photoelectric conversion portion 400, although the transfer transistor 410 is turned off, signal charge generated by the photoelectric conversion portion 400 leaks to the FD portion 420. This causes a decrease in voltage of the FD portion 420 and a decrease in voltage of the signal line 30. The operation state at this time is referred to as “blooming”, which is represented by the dashed line in FIG. 10. If blooming occurs, the voltage of the signal line 30 decreases, compared to the normal operation in which no high-luminance light strikes the photoelectric conversion portion 400, which causes no blooming. The amount of decrease in voltage of the signal line 30 (a level at which the dashed line stops descending) with blooming is determined based on the threshold voltage, the gate width, and the gate length of the second transistor 80 and the voltage V2 supplied to the gate of the second transistor 80 via the second bias line 90. This is because the decrease in voltage of the FD portion 420 causes the first transistor 50 to become greater in driving power than the amplification transistor 430, and the voltage of the signal line 30 is limited to a first range. Specifically, the second transistor 80 limits the variable range of the voltage of the signal line 30 to the first range.

During the period from time t2 to time t5, the ramp signal RAMP fed to the comparator 130 changes in voltage over time. If no blooming occurs, at time t3, the magnitude relationship between the ramp signal RAMP and the pixel signal of the signal line 30 that are inputs of the comparator 130 is changed, and this changes an output of the comparator 130. On the other hand, if blooming occurs, at time t4, the magnitude relationship between the ramp signal RAMP and the pixel signal of the signal line 30 that are inputs of the comparator 130 is changed, and this changes an output of the comparator 130. The time it takes for the change to occur is measured by the counter 160, and the measured time is held in the first memory 140, whereby AD conversion is performed on the reset-level signal. At time t5, the ramp signal RAMP is reset. At this time, if blooming occurs, an error occurs in the result of the AD conversion on the reset-level signal. This will be described below.

At time t6, the control signal TX is changed to a high level. As a result, the transfer transistor 410 is turned on, and the signal charge is transferred from the photoelectric conversion portion 400 to the FD portion 420. The voltage of the FD portion 420 decreases according to the amount of the transferred signal charge. Further, during the period from time t6 to time t8, the voltage V2 changes in value over time.

During the normal operation in which no blooming occurs, a decrease in voltage of the FD portion 420 causes a decrease in voltage of the signal line 30. On the other hand, if blooming occurs, since the amplification transistor 430 is off, the voltage of the signal line 30 is not affected by a decrease in voltage of the FD portion 420. However, a decrease in the voltage V2 causes a decrease in voltage of the signal line 30. Specifically, the second transistor 80 limits the variable range of the voltage of the signal line 30 to a second range different from the first range.

At time t7, the control signal TX is changed to a low level, and the transfer transistor 410 is turned off.

During the period from time t9 to time t11, the ramp signal RAMP fed to the comparator 130 changes in voltage again over time. Then, at time t10, the magnitude relationship between the ramp signal RAMP and the pixel signal of the signal line 30 that are inputs of the comparator 130 is changed, and this changes an output of the comparator 130 again. The time it takes for the change to occur is measured by the counter 160, and the measured time is held in the first memory 140, whereby AD conversion is performed on the photoelectric conversion signal. Finally, an output from the pixel 20 is obtained through a CDS operation of performing differential processing between the result of the AD conversion on the photoelectric conversion signal and the result of the AD conversion on the reset-level signal. Even though blooming occurs, a saturated output is still obtained by maintaining an amount of decrease in potential of the signal line 30 at time t6 at a predetermined level or higher. Specifically, even though an error occurs in the result of the AD conversion on the reset-level signal as described above, a saturated output after CDS is still obtained, which is an appropriate result.

At time t11, the ramp signal RAMP is reset again. At time t12, the control signal RES is changed to a high level. Accordingly, the reset transistor 455 is turned on, and the FD portion 420 is reset. This causes the voltage of the signal line 30 to return to the reset level.

As described above, the photoelectric conversion apparatus according to the present exemplary embodiment includes the first transistors 50, the first bias line 60, the first switches 70, the second transistors 80, the second bias line 90, and the second switches 100. According to the present exemplary embodiment, the first transistor 50 and the second transistor 80 are used for different purposes of use, which makes it possible to optimize characteristics of each transistor and each circuit driving the transistor for each purpose of use. For example, a transistor with a relatively large size employed for correction value acquisition can reduce noise in correction values. Further, as another example, a relatively increased power of a circuit that generates a voltage to be supplied to the gate of a transistor employed for correction value acquisition can reduce noise during the correction value acquisition.

Furthermore, the number of transistors connected to one bias line is smaller in the present exemplary embodiment than in the reference example illustrated in FIG. 4, and the smaller the number of transistors is, the smaller the transistor capacitance that affects operations of the signal line drive portions 40 is. This makes it possible to perform a voltage switching operation at high speed in switching a voltage supplied to the gate of a transistor during the correction value acquisition operation and the pixel signal reading operation. Thus, the present exemplary embodiment allows improvement in performance of the photoelectric conversion apparatus.

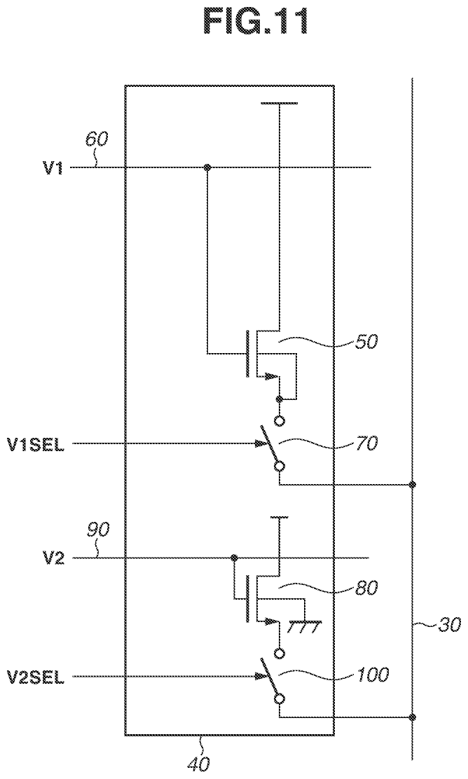

A photoelectric conversion apparatus according to a fifth exemplary embodiment of the present disclosure will be described below with reference to FIG. 11. Like numbers refer to like components corresponding to components according to the first, second, third, and fourth exemplary embodiments, and redundant descriptions thereof will be sometimes omitted or simplified.

While driving according to the present exemplary embodiment is performed as illustrated in FIGS. 8 to 10, the present exemplary embodiment differs from the fourth exemplary embodiment in that the back gates of the first transistor 50 and the second transistor 80 are connected to different destinations. FIG. 11 illustrates an example of a circuit diagram illustrating the photoelectric conversion apparatus according to the present exemplary embodiment.

As illustrated in FIG. 11, the photoelectric conversion apparatus includes signal line drive portions 40. In each signal line drive portion 40, the first transistor 50, the first bias line 60, the first switch 70, the second transistor 80, the second bias line 90, and the second switch 100 are arranged. The first transistor 50 and the second transistor 80 can differ from each other in at least one of threshold voltage, gate width, and gate length. Further, the first transistor 50 and the second transistor 80 can be the same in threshold voltage, gate width, and gate length.

The first transistor 50 is connected to the signal line 30 via the source of the first transistor 50, and the second transistor 80 is connected to the signal line 30 via the source of the second transistor 80. Further, the first transistor 50 and the second transistor 80 are connected to the signal line 30 in parallel with each other. Further, the first switch 70 is connected between the first transistor 50 and the signal line 30 and is driven by the control signal V1SEL. Further, the second switch 100 is connected between the source of the second transistor 80 and the signal line 30 and is driven by the control signal V2SEL. Further, the first bias line 60 is connected to the gate of the first transistor 50. Further, the second bias line 90 is connected to the gate of the second transistor 80.

Further, the voltage V1 is supplied to the gate of the first transistor 50 via the first bias line 60. Further, the voltage V2 is supplied to the gate of the second transistor 80 via the second bias line 90. Further, the voltages V1 and V2 differ from each other, and the first bias line 60 and the second bias line 90 are electrically separated from each other. The back gate of the first transistor 50 is connected to the source of the first transistor 50, the back gate of the second transistor 80 is connected to a ground voltage node. The first switch 70 and the second switch 100 can have a configuration similar to that illustrated in FIG. 1 according to the first exemplary embodiment. Specifically, the first switch 70 can be connected between the power supply voltage node and the drain of the first transistor 50, and the second switch 100 can be connected between the power supply voltage node and the drain of the second transistor 80.

As described above, the photoelectric conversion apparatus according to the present exemplary embodiment includes the first transistor 50, the first bias line 60, the first switch 70, the second transistor 80, the second bias line 90, and the second switch 100. According to the present exemplary embodiment, the back gate of the first transistor 50 is connected to the source of the first transistor 50, and the back gate of the second transistor 80 is connected to the ground voltage node, whereby high-quality signals are acquired when the transistors 50 and 80 are used for different purposes. In the correction value acquisition using the first transistor 50, linearity of gain values acquired for each column to calculate correction values improves. Specifically, high-quality correction values are acquired. Further, in the pixel signal reading using the second transistor 80, parasitic capacitance between the signal line 30 and the second bias line 90 is decreased, which prevents interference between pixel columns in the pixel signal reading. Thus, the present exemplary embodiment allows improvement in performance of the photoelectric conversion apparatus.

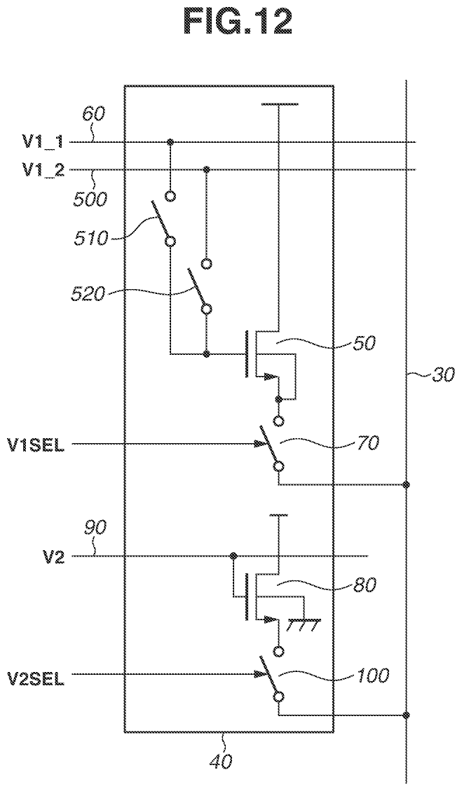

A photoelectric conversion apparatus according to a sixth exemplary embodiment of the present disclosure will be described below with reference to FIG. 12. Like numbers refer to like components corresponding to components according to the first, second, third, fourth, and fifth exemplary embodiments, and redundant descriptions thereof will be sometimes omitted or simplified.

While driving according to the present exemplary embodiment is performed as illustrated in FIGS. 8 to 10, the present exemplary embodiment differs from the fourth and fifth exemplary embodiments in that a plurality of bias lines is provided to supply different voltages to the gate of the first transistor 50. FIG. 12 illustrates an example of a circuit diagram illustrating the photoelectric conversion apparatus according to the present exemplary embodiment.

As illustrated in FIG. 12, the photoelectric conversion apparatus includes signal line drive portions 40. In each signal line drive portion 40, the first transistor 50, the first bias line 60, the first switch 70, the second transistor 80, the second bias line 90, and the second switch 100 are arranged. Furthermore, a third bias line 500, a third switch 510, and a fourth switch 520 are arranged in the signal line drive portion 40. The first transistor 50 and the second transistor 80 can differ from each other in at least one of threshold voltage, gate width, and gate length. Further, the first transistor 50 and the second transistor 80 can be the same in threshold voltage, gate width, and gate length.

The first transistor 50 is connected to the signal line 30 via the source of the first transistor 50, and the second transistor 80 is connected to the signal line 30 via the source of the second transistor 80. Further, the first transistor 50 and the second transistor 80 are connected to the signal line 30 in parallel with each other. Further, the first switch 70 is connected between the first transistor 50 and the signal line 30 and is driven by the control signal V1SEL. Further, the second switch 100 is connected between the second transistor 80 and the signal line 30 and is driven by the control signal V2SEL. Further, the third switch 510 is placed between the gate of the first transistor 50 and the first bias line 60, and the fourth switch 520 is placed between the gate of the first transistor 50 and the third bias line 500. Further, the first bias line 60 is connected to the gate of the first transistor 50. Further, the third bias line 500 is connected to the gate of the first transistor 50. Further, the second bias line 90 is connected to the gate of the second transistor 80. Further, a voltage V1_1 is supplied to the gate of the first transistor 50 via the first bias line 60. Further, a voltage V1_2 is supplied to the gate of the first transistor 50 via the third bias line 500. Further, the voltage V2 is supplied to the gate of the second transistor 80 via the second bias line 90. As illustrated in FIG. 9, the voltage V1 is changed in the gain error correction value acquisition, and the voltage V1_1 corresponds to the voltage V1 before the change whereas the voltage V1_2 corresponds to the voltage V1 after the change. Further, the voltages V1_1, V1_2, and V2 differ from each other, and the first bias line 60, the second bias line 90, and the third bias line 500 are electrically separated from each other. The back gate of the first transistor 50 is connected to the source of the first transistor 50, and the back gate of the second transistor 80 is connected to the ground voltage node. The first switch 70 and the second switch 100 can have a configuration similar to that illustrated in FIG. 1 according to the first exemplary embodiment. Specifically, the first switch 70 can be connected between the power supply voltage node and the drain of the first transistor 50, and the second switch 100 can be connected between the power supply voltage node and the drain of the second transistor 80.

As illustrated in FIG. 9, according to the fourth and fifth exemplary embodiments, the voltage V1 supplied to the gate of the first transistor 50 is changed by changing the voltage V1 supplied to the first bias line 60 in the correction value acquisition. On the other hand, according to the present exemplary embodiment, the first bias line 60 to which the voltage V1_1 is supplied and the third bias line 500 to which the voltage V1_2 is supplied are switched by switching the third switch 510 and the fourth switch 520, whereby the present exemplary embodiment changes the voltage V1 supplied to the gate of the first transistor 50 in the gain error correction value acquisition.

As described above, the photoelectric conversion apparatus according to the present exemplary embodiment includes the first transistor 50, the first bias line 60, the first switch 70, the second transistor 80, the second bias line 90, and the second switch 100. Furthermore, the third bias line 500, the third switch 510, and the fourth switch 520 are included according to the present exemplary embodiment. The present exemplary embodiment changes the voltage V1 supplied to the gate of the first transistor 50 in the correction value acquisition by switching between the plurality of bias lines 60 and 90 to which different voltages are supplied, using the switches 70 and 100. To change the voltage V1 supplied to the gate of the first transistor 50 using a single bias line, the capacitance associated with the bias line needs to be discharged. This makes it difficult to increase the speed of the operation of changing the voltage V1. The present exemplary embodiment makes it possible to increase the speed of the operation of changing the voltage V1 by providing the plurality of bias lines to which different voltages are supplied. Thus, the present exemplary embodiment allows improvement in performance of the photoelectric conversion apparatus.

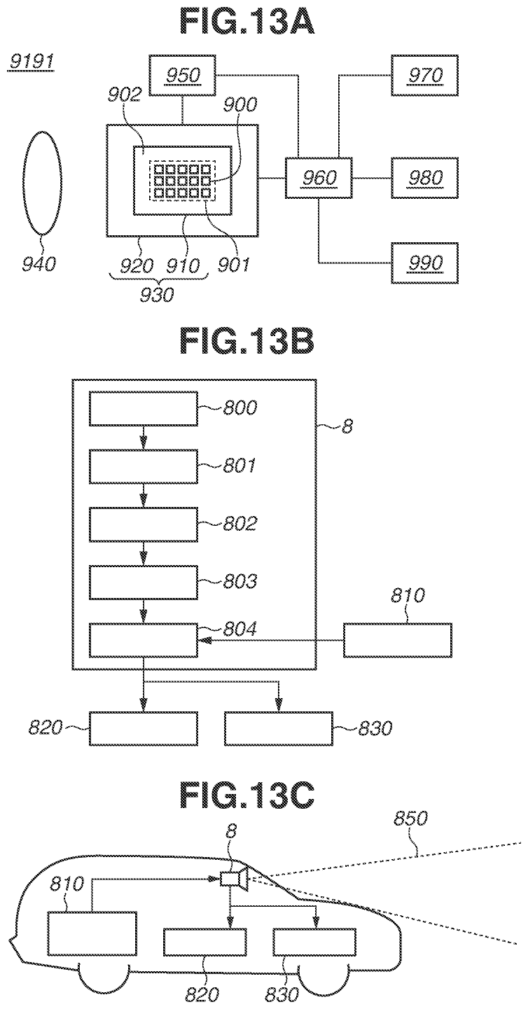

A seventh exemplary embodiment is applicable to any one of the first to sixth exemplary embodiments. FIG. 13A is a schematic diagram illustrating equipment 9191 including a semiconductor apparatus 930 according to the present exemplary embodiment. The semiconductor apparatus 930 can use a photoelectric conversion apparatus according to any one of the above-described exemplary embodiments. The equipment 9191 including the semiconductor apparatus 930 will be described in detail. The semiconductor apparatus 930 can include a semiconductor device 910. The semiconductor apparatus 930 can include a package 920 for storing the semiconductor device 910, in addition to the semiconductor device 910. The package 920 can include a substrate to which the semiconductor device 910 is fixed and a cover, such as a glass, facing the semiconductor device 910. The package 920 can further include a bonding member, such as bonding wires and bumps, connecting terminals provided to the substrate and terminals provided to the semiconductor device 910.

The equipment 9191 can include at least one of an optical apparatus 940, a control apparatus 950, a processing apparatus 960, a display apparatus 970, a storage apparatus 980, and a mechanical apparatus 990. The optical apparatus 940 corresponds to the semiconductor apparatus 930. The optical apparatus 940 includes an optical system, such as a lens, a shutter, and a mirror, that guides light to the semiconductor apparatus 930. The control apparatus 950 controls the semiconductor apparatus 930. The control apparatus 950 is, for example, a photoelectric conversion apparatus, such as an application-specific integrated circuit (ASIC).

The processing apparatus 960 processes signals output from the semiconductor apparatus 930. The processing apparatus 960 is a photoelectric conversion apparatus, such as a central processing unit (CPU) and an ASIC, for forming an analog front end (AFE) or a digital front end (DFE). The display apparatus 970 is an electroluminescent (EL) display apparatus or a liquid crystal display apparatus and displays information (image) acquired by the semiconductor apparatus 930. The storage apparatus 980 is a magnetic device or a semiconductor device and stores information (image) acquired by the semiconductor apparatus 930. The storage apparatus 980 is a volatile memory, such as a static random-access memory (SRAM) or a dynamic random-access memory (DRAM) or a non-volatile memory, such as a flash memory or a hard disk drive.

The mechanical apparatus 990 includes a movable portion or a propulsion portion, such as a motor and an engine. The equipment 9191 displays signals output from the semiconductor apparatus 930 on the display apparatus 970 and transmits the signals to the outside via a communication apparatus (not illustrated) of the equipment 9191. Thus, the equipment 9191 desirably includes the storage apparatus 980 and the processing apparatus 960 separately from a storage circuit and a calculation circuit of the semiconductor apparatus 930. The mechanical apparatus 990 can be controlled based on signals output from the semiconductor apparatus 930.

Further, the equipment 9191 is suitable for use as electronic equipment, such as an information terminal with an imaging function (e.g., smartphone, wearable terminal) and a camera (e.g., camera with interchangeable lenses, compact camera, video camera, monitoring camera). The mechanical apparatus 990 of a camera is capable of driving components of the optical apparatus 940 for zooming, focusing, and shutter operations. Further, the mechanical apparatus 990 of a camera is capable of moving the semiconductor apparatus 930 for anti-vibration operations.

Further, the equipment 9191 can be transportation equipment, such as a vehicle, a ship, or a flying object (such as drone or airplane). The mechanical apparatus 990 of transportation equipment can be used as a moving apparatus. The equipment 9191 as transportation equipment is suitable for use in transporting the semiconductor apparatus 930 or assisting in and/or automating driving (navigation) using an imaging function. The processing apparatus 960 for assisting in and/or automating driving (navigation) is capable of performing processing for operating the mechanical apparatus 990 as a moving apparatus based on information acquired by the semiconductor apparatus 930. Further, the equipment 9191 can be medical equipment, such as an endoscope, measurement equipment, such as a distance sensor, analysis equipment, such as an electron microscope, office equipment, such as a copy machine, or industrial equipment, such as a robot.

Each exemplary embodiment described above makes it possible to provide suitable pixel characteristics. This increases the value of the photoelectric conversion apparatus. The increase of the value herein corresponds to at least one of an added function, improved performance, an improved characteristic, improved reliability, an improved manufacturing yield, a reduced environmental impact, a reduced cost, a reduced size, and a reduced weight.

Thus, use of the semiconductor apparatus 930 according to the present exemplary embodiment in the equipment 9191 increases the value of the equipment 9191. For example, use of the semiconductor apparatus 930 in transportation equipment makes it possible to achieve excellent performance in imaging the outside of the transportation equipment and measuring external environments. Thus, determining to use the photoelectric conversion apparatus according to the present exemplary embodiment in transportation equipment is advantageous for improving performance of the transportation equipment in manufacturing and selling the transportation equipment. The semiconductor apparatus 930 is especially suitable for use to assist transportation equipment in driving and/or for use in transportation equipment that performs automated driving using information acquired by the photoelectric conversion apparatus.

A photoelectric conversion system and a moving object according to the present exemplary embodiment will be described with reference to FIGS. 13B and 13C.

FIG. 13B illustrates an example of a photoelectric conversion system relating to an in-vehicle camera. A photoelectric conversion system 8 includes a photoelectric conversion apparatus 800. The photoelectric conversion apparatus 800 is a photoelectric conversion apparatus (image capturing apparatus) according to one of the above-described exemplary embodiments. The photoelectric conversion system 8 includes an image processing unit 801 and a parallax acquisition unit 802. The image processing unit 801 performs image processing on a plurality of pieces of image data acquired by the photoelectric conversion apparatus 800. The parallax acquisition unit 802 calculates a parallax (phase difference between parallax images) from a plurality of pieces of image data acquired by the photoelectric conversion system 8. The photoelectric conversion system 8 can include an optical system (not illustrated), such as a lens, a shutter, and a mirror, that guides light to the photoelectric conversion apparatus 800. Further, a plurality of photoelectric conversion portions that is substantially conjugate to a pupil of the optical system can be arranged in pixels of the photoelectric conversion apparatus 800. For example, the plurality of photoelectric conversion portions that is substantially conjugate to a pupil is arranged in correspondence with a single micro-lens. The plurality of photoelectric conversion portions receives light beams having transmitted through different positions of pupils of the optical system from each other, and the photoelectric conversion apparatus 800 outputs image data corresponding to the light beams having transmitted through the different positions. Then, the parallax acquisition unit 802 can calculate a parallax using the output image data. Further, the photoelectric conversion system 8 includes a distance acquisition unit 803 and a collision determination unit 804. The distance acquisition unit 803 calculates a distance to a target object based on the calculated parallax, and the collision determination unit 804 determines whether there is a possibility of collision based on the calculated distance. The parallax acquisition unit 802 and the distance acquisition unit 803 are an example of a distance information acquisition unit that acquires distance information about a distance to a target object. Specifically, the distance information is information about a parallax, a defocus amount, and a distance to a target object. The collision determination unit 804 can determine a possibility of collision using any of the distance information. The distance information can be acquired using ToF. The distance information acquisition unit can be implemented using dedicated hardware or a software module. Further, the distance information acquisition unit can be implemented using a field programmable gate array (FPGA), an ASIC, or a combination thereof.

The photoelectric conversion system 8 is connected to a vehicle information acquisition apparatus 810 and acquires vehicle information, such as a vehicle speed, a yaw rate, and a steering angle. Further, the photoelectric conversion system 8 is connected to a control engine control unit (control ECU) 820. The control ECU 820 is a control apparatus that outputs control signals for generating a braking force against the vehicle based on a result of the determination by the collision determination unit 804. Further, the photoelectric conversion system 8 is also connected to a warning apparatus 830. The warning apparatus 830 provides a warning to a driver based on a result of the determination by the collision determination unit 804. For example, if the collision determination unit 804 determines that there is a high possibility of collision, the control ECU 820 performs vehicle control to avoid collision or reduce damage by applying a brake, releasing an accelerator, and/or reducing engine output. The warning apparatus 830 warns a user by producing a warning, such as a sound, displaying warning information on a screen of a car navigation system, or vibrating a seat belt or steering.

According to the present exemplary embodiment, the photoelectric conversion system 8 captures images around, e.g., in front of or behind, the vehicle.

FIG. 13C illustrates a photoelectric conversion system in capturing images in front of the vehicle (image capturing range 850). The vehicle information acquisition apparatus 810 transmits instructions to the photoelectric conversion system 8 or the photoelectric conversion apparatus 800. The foregoing configuration further improves distance measurement accuracy.

While the control performed to avoid collision with another vehicle is described above as an example, applications to other controls for autonomous driving to follow another vehicle or autonomous driving to stay within a lane are also possible. Furthermore, the photoelectric conversion system 8 is applicable to not only a vehicle, such as a car, but also a moving object (moving apparatus), such as a ship, an airplane, or an industrial robot. Furthermore, the photoelectric conversion system 8 is applicable to not only a moving object but also equipment that widely uses object recognition, such as an intelligent transportation system (ITS).

In the present specification, unless otherwise specified, the phrases “A or B”, “at least one of A and B”, “at least one of A or/and B”, and “one or more of A or/and B” each encompass all possible combinations of listed items. Specifically, it is understood that the phrases disclose all cases: a case where at least one A is included, a case where at least one B is included, and a case where at least one A and at least one B are included. The same applies to combinations of three or more elements.

The above-described exemplary embodiments can be changed as appropriate within the technical spirit. The disclosure of the present specification encompasses not only those described in the present specification but also all matters discernible from the present specification and the drawings attached to the present specification. Further, the disclosure of the present specification encompasses complements of concepts described in the present specification. Specifically, in a case where the present specification includes, for example, the phrase “A is greater than B”, even if the phrase “A is not greater than B” is omitted, it is understood that the present specification discloses the information “A is not greater than B” because the inclusion of the phrase “A is not greater than B” is based on the premise that the case where “A is not greater than B” has been considered.

The present disclosure allows improvement in performance of a photoelectric conversion apparatus including a plurality of transistors connected to a signal line.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-190918, filed Nov. 30, 2022, which is hereby incorporated by reference herein in its entirety.

What is claimed is:

1. A photoelectric conversion apparatus comprising:
a pixel configured to generate a pixel signal through photoelectric conversion;
a signal line to which the pixel signal is output;
a first transistor connected to the signal line;
a second transistor connected to the signal line;
a first switch connected to the first transistor; and
a second switch connected to the second transistor,
wherein the first transistor and the second transistor are connected to the signal line in parallel with each other,
wherein a gate of the first transistor is connected to a first bias line,
wherein a gate of the second transistor is connected to a second bias line,
wherein the first bias line and the second bias line are electrically separated from each other, and
wherein a first control line of the first switch and a second control line of the second switch are electrically separated from each other.

2. The photoelectric conversion apparatus according to claim 1, wherein a voltage supplied to the gate of the first transistor via the first bias line differs from a voltage supplied to the gate of the second transistor via the second bias line.

3. The photoelectric conversion apparatus according to claim 1, wherein the second switch is in an off state at a timing when the first switch is in an on state.

4. The photoelectric conversion apparatus according to claim 1, wherein a first mode in which the second switch is in an off state at a timing when the first switch is in an on state and a second mode in which the first switch is in an off state at a timing when the second switch is in an on state are switched.

5. The photoelectric conversion apparatus according to claim 1, wherein the first transistor limits a variable range of a voltage of the signal line.

6. The photoelectric conversion apparatus according to claim 1, wherein the first transistor and the second transistor limit a variable range of a voltage of the signal line, the first transistor limits the variable range of the voltage of the signal line to a first range, and the second transistor limits the variable range of the voltage of the signal line to a second range different from the first range.

7. The photoelectric conversion apparatus according to claim 1, wherein the first transistor is connected to the signal line via a source of the first transistor, and the second transistor is connected to the signal line via a source of the second transistor.

8. The photoelectric conversion apparatus according to claim 7, wherein the first switch is connected between a power supply voltage node and a drain of the first transistor, and the second switch is connected between a power supply voltage node and a drain of the second transistor.

9. The photoelectric conversion apparatus according to claim 7, wherein the first switch is connected between the first transistor and the signal line, and the second switch is connected between the second transistor and the signal line.

10. The photoelectric conversion apparatus according to claim 7, wherein a back gate of the first transistor is connected to the source of the first transistor.

11. The photoelectric conversion apparatus according to claim 10, wherein a back gate of the second transistor is connected to a ground voltage node.

12. The photoelectric conversion apparatus according to claim 10, wherein a third bias line is connected to the gate of the first transistor, and the first bias line and the third bias line are electrically separated from each other.

13. The photoelectric conversion apparatus according to claim 12, wherein a voltage supplied to the gate of the first transistor via the third bias line differs from a voltage supplied to the gate of the first transistor via the first bias line.

14. The photoelectric conversion apparatus according to claim 12, wherein a third switch is connected between the gate of the first transistor and the first bias line, and a fourth switch is connected between the gate of the first transistor and the third bias line.

15. The photoelectric conversion apparatus according to claim 1, wherein a voltage supplied from the first bias line to the first transistor changes at a timing when a transfer transistor of the pixel to generate the pixel signal is in an on state.

16. The photoelectric conversion apparatus according to claim 1, wherein the first transistor and the second transistor differ in set threshold voltage from each other.

17. The photoelectric conversion apparatus according to claim 1, wherein the first transistor and the second transistor differ in gate width from each other.

18. The photoelectric conversion apparatus according to claim 1, wherein the first transistor and the second transistor differ in gate length from each other.

19. A photoelectric conversion apparatus comprising:
a pixel configured to generate a pixel signal through photoelectric conversion;
a signal line to which the pixel signal is output;
a first transistor connected to the signal line;
a second transistor connected to the signal line;
a first switch connected to the first transistor; and
a second switch connected to the second transistor,
wherein the first transistor and the second transistor are connected to the signal line in parallel with each other,
wherein a gate of the first transistor is connected to a first bias line,
wherein a gate of the second transistor is connected to a second bias line,
wherein the first bias line and the second bias line are electrically separated from each other, and
wherein the first transistor limits a variable range of a voltage of the signal line.

20. The photoelectric conversion apparatus according to claim 19, wherein the first transistor is connected to the signal line via a source of the first transistor, and the second transistor is connected to the signal line via a source of the second transistor.

21. A photoelectric conversion apparatus comprising:
a pixel configured to generate a pixel signal through photoelectric conversion;
a signal line to which the pixel signal is output;
a first transistor connected to the signal line; and
a second transistor connected to the signal line,
wherein the first transistor and the second transistor are connected to the signal line in parallel with each other,
wherein a first switch is connected between the first transistor and the signal line, and
wherein a second switch is connected between the second transistor and the signal line.

22. The photoelectric conversion apparatus according to claim 21, wherein the first transistor is connected to the signal line via a source of the first transistor, and the second transistor is connected to the signal line via a source of the second transistor.

23. The photoelectric conversion apparatus according to claim 21, wherein a gate of the first transistor and a gate of the second transistor are connected to a common bias line.

24. Equipment comprising:
the photoelectric conversion apparatus according to claim 1; and
at least one of:
an optical apparatus configured to guide light to the photoelectric conversion apparatus,
a control apparatus configured to control the photoelectric conversion apparatus,
a processing apparatus configured to process a signal output from the photoelectric conversion apparatus,
a display apparatus configured to display information obtained by the photoelectric conversion apparatus,
a storage apparatus configured to store the information obtained by the photoelectric conversion apparatus, and
a mechanical apparatus configured to operate based on the information obtained by the photoelectric conversion apparatus.
